(19) United States
(12) Patent Application Publication
(10) Pub. No.: US 2026/0050706 A1
(43) Pub. Date: Feb. 19, 2026

(54) CLOCK TIMING IN REPLICATED ARRAYS

(71) Applicant: Tesla, Inc., Austin, TX (US)

(72) Inventors: Anantha Kumar Nivarti, Fremont, CA (US); Te-Chen Tsai, Sunnyvale, CA (US); Derek Carson, San Jose, CA (US); Raghuvir Ramachandran, Los Gatos, CA (US); Timothy Fischer, Denver, CO (US)

(21) Appl. No.: 19/103,790

(22) PCT Filed: Aug. 16, 2023
(86) PCT No.: PCT/US2023/072285

§ 371 Date: Feb. 13, 2025

Related U.S. Application Data
(60) Provisional application No. 63/371,993, filed on Aug. 19, 2022.

(51) Int. Cl. G06F 30/20

(52) U.S. Cl. CPC G06F 30/20

(57) ABSTRACT

The present disclosure relates to systems and methods for simulating clock timing distribution across a node array (204). An example method includes accessing a timing model of a compute node (206) that the timing model of the compute node (206) represents timing data associated with clock signal propagation between the compute node (206) and four neighboring nodes of the node array (204) that each abut the compute node (206) and simulating, using a computing device, clock signal timing distribution for a majority of the nodes of the node array (204) using the timing model of the compute node (206).

### CROSS-REFERENCE TO PRIORITY APPLICATION

This application claims the benefit of priority of U.S. Provisional Application No. 63/371,993, filed Aug. 19, 2022, and titled “CLOCK TIMING IN REPLICATED ARRAYS,” the disclosure of which is hereby incorporated by reference in its entirety and for all purposes.

### BACKGROUND

### Technical Field

This disclosure relates generally to distributed clocking, and more particularly to techniques for modeling clocking in arrays.

### Description of Related Technology

A high-density processing system can be constructed using an array of processing nodes. The nodes can communicate with neighboring nodes to perform processing tasks. Communication between nodes can use synchronous and/or asynchronous methods. A clock signal can be provided to each node so that the nodes can be synchronized, which can enable communication therebetween.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a method of simulating a node array. The method includes accessing a timing model of a compute node of the node array that is stored in non-transitory computer readable memory and simulating, using one or more computers, clock signal timing for a majority of the nodes of the node array using the timing model of the compute node. The timing model of the compute node represents timing data associated with clock signal propagation between the compute node and four neighboring nodes of the node array that each abut the compute node.

The method can also include determining a worst case timing for the clock signal in the node array based on the simulating.

The method can also include adjusting a clock distribution network of the node array based on the worst case timing. In addition, adjusting the clock distribution network can include updating of one or more files that represent circuitry of the node array. Furthermore, the method can further include accessing a timing model of a globals node of the node array that is stored in the non-transitory computer readable memory. The determinization can be based on a simulation of clock signal timing that uses the timing model of the globals node.

In the method, the simulating can include simulating mesochronous clocking in the node array.

In the method, the timing model of the node array can model the compute node receiving the clock signal from a first pair of the four neighboring nodes and the compute node providing the clock signal to a second pair of the four neighboring nodes. In addition, the clock signal can be delayed by one unit of delay in the compute node relative to in the first pair of neighboring nodes. Furthermore, the clock signal can be delayed by two units of delay in the second pair of neighboring nodes relative to in the first pair of neighboring nodes.

In the method, the timing model of the node array is a block group timing model. Additionally, the node array can be essentially of instances of the compute node and instances of a globals node.

In the method, the majority of the nodes of the node array can include at least 90% of the nodes of the node array.

The method can further include generating the timing model of the compute node by at least simulating clock signal propagation between the compute node and the four neighboring nodes.

Another aspect of this disclosure is non-transitory computer readable storage comprising instructions that, when executed by one or more processors, cause a method of simulating a node array to be performed. The method includes accessing a timing model of a compute node of the node array that is stored in non-transitory computer readable memory and simulating, using one or more computers, clock signal timing for a majority of the nodes of the node array using the timing model of the compute node. Furthermore, the timing model of the compute node represents timing data associated with clock signal propagation between the compute node and four neighboring nodes of the node array that each abut the compute node.

Another aspect of this disclosure is a computer system for simulating a node array. The system includes non-transitory computer readable memory storing a timing model of a compute node of a node and one or more processor configured to execute instructions to at least access the timing model for the compute node and simulate clock signal timing for a majority of the nodes of the node array using the timing model of the compute node. Additionally, the timing model of the compute node represents timing data associated with clock signal propagation between the compute node and four neighboring nodes of the node array that each abut the compute node.

Another aspect of this disclosure is a system for simulating clock timing distribution across a node array that includes a plurality of compute nodes. The system can include one or more computing devices configured to store a timing model, corresponding to a compute node and four neighboring compute nodes that each neighboring compute code is abutted to the compute node. Additionally, individual computing devices of the one or more computing devices are configured to access the timing model of the compute node and simulate, using a computing device, clock signal timing distribution for a majority of the nodes of the node array using the timing model of the compute node.

Another aspect of this disclosure is a non-transitory computer-readable storage medium storing instructions to simulate clock timing distribution across a node array. The instructions, when executed by a processor, cause the processor to perform operations including accessing a timing model of a compute node and simulating, using a computing device, clock signal timing distribution for a majority of the nodes of the node array using the timing model of the compute node. Additionally, the timing model of the compute node represents timing data associated with clock signal propagation between the compute node and four neighboring nodes of the node array that each abut the compute node.

In the non-transitory computer-readable storage medium, the operations can include determining a worst case timing for the clock signal in the node array based on the simulating. Additionally, the non-transitory computer-readable storage medium can include adjusting a clock distribution network of the node array based on the worst case timing. Adjusting the clock distribution network can include updating of one or more files that represent circuitry of the node array.

In the non-transitory computer-readable storage medium, the operations can include accessing a timing model of a globals node of the node array that is stored in the non-transitory computer readable memory. The determination is based on a simulation of clock signal timing that uses the timing model of the globals node.

In the non-transitory computer-readable storage medium, the simulating includes simulating mesochronous clocking in the node array

In the non-transitory computer-readable storage medium, the timing model of the node array can model the compute node receiving the clock signal from a first pair of the four neighboring nodes and the compute node providing the clock signal to a second pair of the four neighboring nodes. In addition, the clock signal can be delayed by one unit of delay in the compute node relative to in the first pair of neighboring nodes. Furthermore, the clock signal can be delayed by two units of delay in the second pair of neighboring nodes relative to in the first pair of neighboring nodes.

In the non-transitory computer-readable storage medium, the timing model of the node array can be a block group timing model. Additionally, the node array can consist essentially of instances of the compute node and instances of a globals node.

In the non-transitory computer-readable storage medium, the majority of the nodes of the node array can include at least 90% of the nodes of the node array.

In the non-transitory computer-readable storage medium, the operations can also include generating the timing model of the compute node by at least simulating clock signal propagation between the compute node and the four neighboring nodes.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will be described, by way of non-limiting examples, with reference to the accompanying drawings.

FIG. 1 is a schematic block diagram of an example chip in accordance with aspects of this disclosure.

FIG. 2A is a schematic diagram of a clock distribution network according to an embodiment.

FIG. 2B illustrates an example implementation of the clock distribution circuitry within an example node of the node array of FIG. 2A.

FIG. 2C illustrates another example implementation of the clock distribution circuitry within an example node of the node array of FIG. 2A.

FIG. 3A is a node clock-level map associated with an example node array such as the node array of FIG. 2A.

FIG. 3B is a node clock-level topology corresponding to the node clock-level map of FIG. 3A.

FIG. 4 illustrates an example implementation of the node array of FIG. 1.

FIG. 5 illustrates the characterization of the node array of FIG. 1 to model the clock timing distribution across the node array.

FIG. 6 illustrates an example of a block of the node array of FIG. 5.

FIG. 7 illustrates an example embodiment of a computing device.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. The headings provided herein are for convenience only and do not necessarily affect the scope or meaning of the claims.

### Introduction to Distributed Clocking for a Node Array

This disclosure relates to a clock distribution network with a clock signal that arrives at different times at various nodes of a node array. Generating a clock signal with fixed offsets can be referred to as mesochronous clocking. Embodiments disclosed herein relate to a mesochronous clock network that is built modularly of common circuitry. The clock signals of such a network can be locally low-skew and mesochronous at a coarser level.

The principles and advantages disclosed herein can be applied to any suitable circuit chip. In certain applications, the distribution of clock signals as disclosed herein can be applied to chips that each include an array of smaller compute nodes. The compute nodes can be referred to as processors or cores. In this way, the clock signals can form an arrival-time wave across the array of compute nodes. Each compute node can receive a low skew clock in one embodiment. A compute node of the array can be designed with only the interface to neighboring compute nodes accounting for the arrival-time difference (skew) of the mesochronous clock phases. The techniques described herein can be applied to a node array that is square (equal rows and columns) or a node array that is rectangular with a different number of rows than columns.

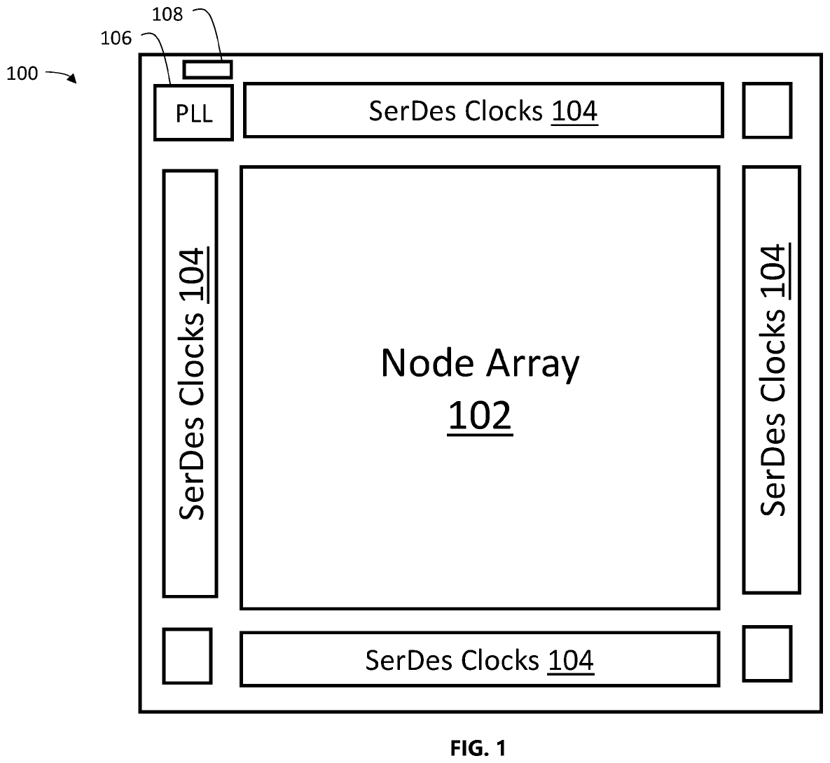

FIG. 1 is a schematic block diagram of an example chip 100 in accordance with aspects of this disclosure. The chip 100 can be an integrated circuit die. The chip 100 can include a node array 102 (also referred to as a computational node array) with distributed clocking, one or more Serializer/Deserializer (SerDes) clock blocks 104, a clock generator 106, and a clock controller 108. The SerDes clock blocks 104 can interface with other chips 100 forming an array of chips 100. In certain application instances, the node array 102 can be included on a chip 100 in a system-on-wafer system, an array of chips 100 on a printed circuit board, or the like. In certain applications, the node array 102 of FIG. 1 can be implemented on a system on a wafer that is packaged with a wafer-level packaging structure. As shown in the embodiment of FIG. 1, the clock generator 106 can be implemented external to the node array 102. In some embodiments, the clock generator 106 can include a phase-locked loop (PLL). The clock generator 106 can be arranged to provide a clock signal to a compute node at a corner of the node array 102. The clock controller 108 can also be implemented outside of the node array 102. The nodes within the node array 102 can include node to node interfaces that can be configured to communicate synchronously. A core to Serializer/Deserializer (SerDes) interface can be asynchronous. In some embodiments, the PLL is operating off 100 MHz reference frequency band, although other frequency bands are contemplated to be within the scope of the present disclosure. The PLL may configured to generate source clocks for various operating modes, including functional, bypass and test mode. The PLL may be configured to operate without a glitch source clock selection and to manage any thermal issues and the maximum current through clock throttling. In some examples, clock throttling. OGG (on-chip clock control) for scan capture, and clock ramp up/down are implemented by cycle skipping to modulate effective frequency using, for example, a 32×32 pattern of first in, first out (FIFO).

In the node array 102 with distributed clocking of FIG. 1, each node can be an instance of a computing circuit (also referred to as a processing core or compute node). In certain applications, most of the nodes can be implemented as instances of a computing circuit, and one or more of the nodes can be implemented as instances of a different circuit. Each node of the node array 102 can include an instance of substantially the same clock distribution circuitry even if other circuitry of at least some of the nodes is different than that of other nodes. For example, most of the nodes can be implemented as instances of a computing circuit, and one or more of the nodes can be implemented as instances of a globals node. The globals node can include a process, voltage, and temperature (PVT) sensor (not shown in FIG. 1). In the node array 102, nodes can be tiled and abutted. For example, each node of the node array 102 can be self-contained and interconnected to adjacent node(s) (e.g., abutted node(s)). At the same time, the node array 102 can be implemented without the use of top-level wires, gates, or channels. Accordingly, nodes can be configured to communicate with neighboring nodes with lower-level wires over relatively short connections. In some embodiments, the nodes of the node array 102 can be stepped without mirroring or rotation. In certain implementations, the nodes can be aligned to the grid pitch of the power supply lines (VDD/Vss). For example, the height and width of each node can be multiples of the power supply grid pitch. The power supply grid pitch can further be aligned to a bump pitch.

Each node of the node array 102 can include an instance of substantially the same clock distribution circuitry. The nodes can be designed such that output clock wires of a node are aligned with the input clock wires of its neighboring nodes. The nodes can be stepped and tiled in the node array such that clock output wires align with and electrically connect with clock input wires of neighboring nodes that are arranged downstream to receive the clock signals. With such electrical connections, the node array can be implemented without channels or top-level wiring for clock distribution. In certain embodiments, fanouts of the clock distribution circuitry can be balanced for inverters.

As described herein, the clock signal received at a root node can propagate from the root node to two neighboring nodes with one unit of delay. The root node can be located at a corner of the node array 102. The unit of delay can be a fixed offset for a given node array. The unit of delay can correspond to a delay from buffering the clock signal (e.g., using inverters) and the wire delay associated with the clock signal propagating to its neighboring node(s). For example, in one embodiment one of the two neighboring nodes is in the same row as the root node, and the other of the two neighboring nodes is in the same column as the root node. As one example, the neighboring nodes are positioned to the south and the east of the root node. In this configuration, the clock signal continues to propagate with one more unit of delay to neighboring nodes to the south and east from the two neighboring nodes in the node array in this example. Such clock signal propagation continues through the clock distribution network until the clock signal reaches the node of the node array at an opposite corner from the root node. In some examples, a signal that is routed from an originating node (e.g., node located in the south east corner of the node array 102) to a node that is north or west can travel upstream and lose one unit delay in a node array, and a signal that is routed from an originating node (e.g., node located in the southeast corner of the node array 102) to a node that is south or east can travel downstream and gain one unit delay in a node array. In some applications, signals traveling upstream can be routed faster than signals traveling downstream to account for the unit delay and to meet setup and hold time specifications.

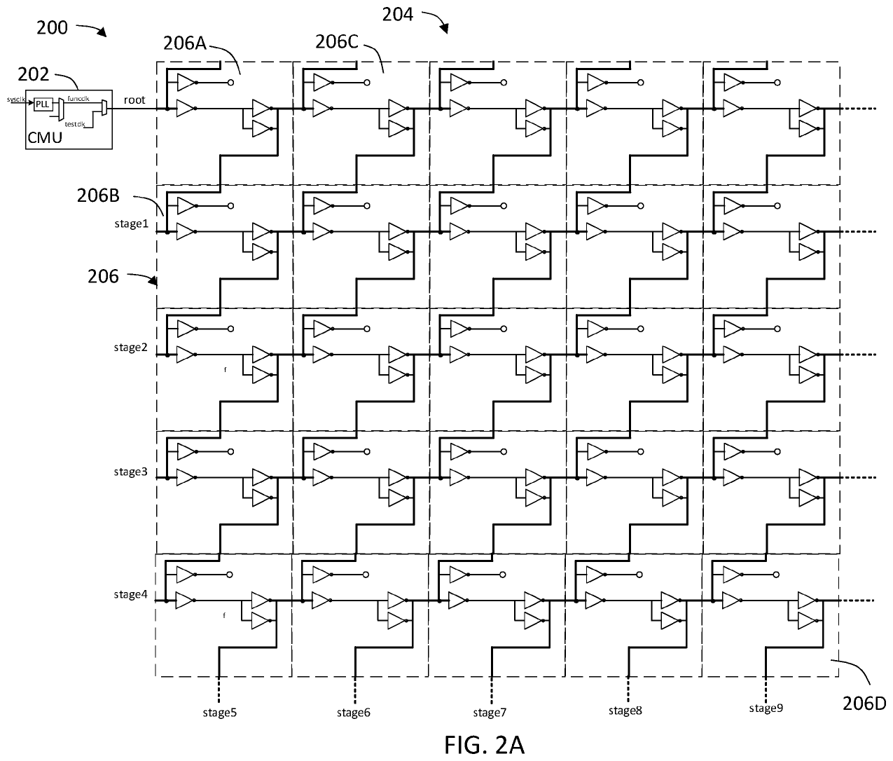

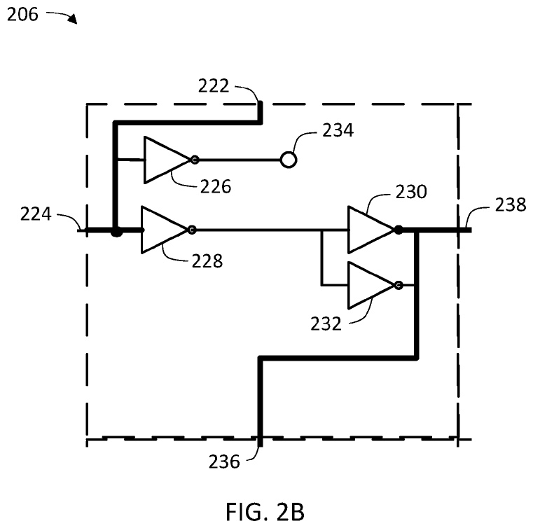

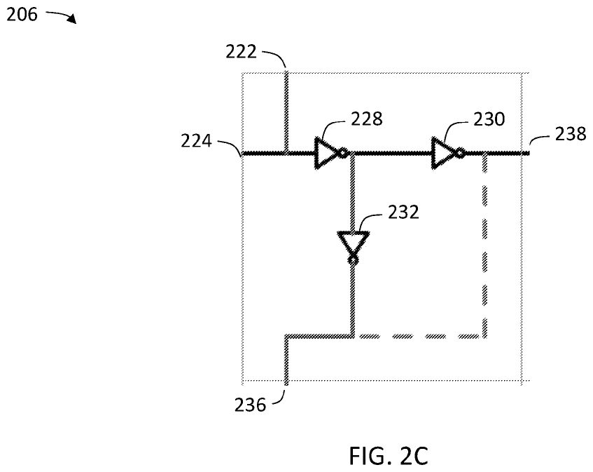

One of the two neighboring nodes can be located in the same row as the root node and the other of the two neighboring nodes can be located in the same column as the root node. In some embodiments, the neighboring nodes abut the root node. As one example, the neighboring nodes are to the south and the east of the root node as shown in FIG. 2A. For example, the neighboring nodes of the node 206A can be the nodes 206B and 206C. The clock signal continues to propagatc with one more unit of delay to neighboring nodes to the south and east from the two neighboring nodes of the root node in the node array in this example. Such clock signal propagation continues through the clock distribution network in the node array 102 until the clock signal reaches a node of the node array 102 at an opposite corner from the root node. In some examples, a signal that is routed from an originating node (e.g., node 206D) that generates the signal to a neighboring node that is north or west of the originating node can travel upstream to the destination node (e.g., node 206A) and lose one unit delay in a node array 102. This signal routing is referred to as upstream signal traveling. A signal that is routed from an originating node (e.g., node 206A) to a neighboring node that is south or east can travel downstream to the destination node (e.g., node 206D) and gain one unit delay in a node array 102. This can be referred to as downstream signal traveling. Signals traveling upstream can be routed faster than signals traveling downstream to account for the unit delay and meet setup and hold time specifications.

FIG. 2A is a schematic diagram of a clock distribution network 200 according to an embodiment. The clock distribution network 200 includes a clock management unit (CMU) 202 and clock distribution circuitry of a node array 204 (also referred to as a clock distribution node array) of nodes 206. Each node 206 includes an instance of a clock distribution circuitry for distributing clock signals within the node array 204. In the embodiment of FIG. 2A, the clock distribution network 200 has a 2D distributed strapped H-tree topology. The CMU 202 is configured to output a clock signal, which is received at a root node 206A of the node array 204.

With reference to FIG. 2A, the root can be located at the input to a node 206 in a corner of the node array 204. For example, the root can be located at the input to a node 206 at the northwest or upper left corner (e.g., node 206A) of the node array 204 illustrated in FIG. 2A. In other embodiments, the root can be the input to another corner (e.g., node 206D) node 206 of a node array 204 when clock signals propagate in a different direction along a row and/or column of nodes. The node 206 that receives a clock signal from external to the node array 204 can be referred to as a root node 206.

Further referring to FIG. 2A, the clock distribution network 200 can be implemented with a node array 204. The node array 204 illustrated in FIG. 2A is an example of the node array 102 with distributed clocking of FIG. 1. In certain embodiments, each node 206 can be an instance of a computing circuit. In certain applications, most of the nodes 206 include instances of a computing circuit and one or more of the remaining nodes 206 include instances of a different circuit, such as a globals node. Globals nodes may refer to nodes 206 that do not include circuitry for performing processing tasks. In some examples, the global nodes can include a process, voltage, and temperature (PVT) sensor. In some implementations, compute nodes and global nodes may both include communication interfaces to enable communication with neighboring nodes 206. In some implementations, the communication interfaces for compute nodes may be the same as the communication interfaces for global nodes.

In certain embodiments, each node 206 of the node array 204 can include an instance of the same clock distribution circuitry even if the other circuitry of one or more of the nodes 206 is different than that of other nodes 206. In one embodiment of the node array 204, the nodes 206 can be tiled and abutted. At the same time, the node array 204 may be implemented without any top-level wires or gates. Accordingly, nodes 206 can communicate with neighboring nodes 206 with lower-level wires over short connections. The nodes 206 of the node array 204 can be stepped without mirroring or rotation. The nodes 206 can also be aligned to a grid pitch of power supply (VDD/VSS) lines. For example, the height and width of each node 206 can be a multiple of the power supply grid pitch. In some embodiments, the power supply grid pitch can further be aligned to a bump pitch.

As shown in FIG. 2A, each node 206 can include an instance of substantially the same clock distribution circuitry. FIG. 2B illustrates an example implementation of the clock distribution circuitry within an example node 206 of the node array 204 of FIG. 2A. With reference to FIGS. 2A and 2B, the clock distribution circuitry includes a first input clock wire 222, a second input clock wire 224, a first inverter 226, a second inverter 228, a third inverter 230, a fourth inverter 232, a clock tap point 234, a first output clock wire 236, and a second output clock wire 238.

The clock distribution circuitry for each of the nodes 206 is designed such that output clock wires 236 and 238 of a node 206 are aligned with input clock wires 222 and 224 of neighboring nodes 206. The nodes 206 can be stepped and tiled in the node array 204 such that the output clock wires 236 and 238 align with and electrically connected with the input clock wires 222 and 224 two of the neighboring nodes 206. Using these electrical connections, the node array 204 can be implemented without the use of channels or top-level wiring for the distribution of the clock.

Returning to FIG. 2B, the input wires 222 and 224 can receive an input clock signal from two of the neighboring nodes 206. For example, the first input clock wire 222 receives an input clock signal from the neighboring node 206 above the current node 206 while the second input clock wire 224 receives an input clock signal from the neighboring node 206 to the left of the current node 206. The first and second input clock wires 222 and 224 provide the clock signal to the first and second inverters 226 and 228. The first inverter 226 inverts the clock signal and provides the inverted clock signal to the clock tap point 234, which is then provided to the primary circuitry of a corresponding node of the computational node array 102 (e.g., the computing circuit or global circuit in certain embodiments).

The second inverter 228 inverts the clock signal and provides the inverted clock signal to the third and fourth inverters 230 and 232. Each of the third and fourth inverters 230 and 232 inverters the inverted clock signal and outputs the resulting clock signal to the first and second output clock wires 236 and 238. The first and second output clock wires 236 and 238 output the clock signal to the neighboring nodes 206 to the right and below the current node 206.

Referring back to FIG. 2A, the clock signal received at the root node 206 (e.g., node 206A) propagates to its two neighboring nodes (e.g., nodes 206B, 206C) below and to the right with one unit of delay. The unit of delay can be a fixed offset for the entire node array 204. In some implementations, the unit of delay can correspond to a delay from buffering the clock signal (e.g., via the inverters 228-232) combined with the wire delay associated with the clock signal propagating to the downstream neighboring nodes 206. In FIG. 2A, one of the downstream neighboring nodes 206 is in the same row as and to the right of the root node 206 and the other of the downstream neighboring nodes 206 is in the same column and below as the root node 206. In other words, the neighboring nodes 206 can be located to the south and the east of the root node 206.

The clock signal will continue to propagate with one more unit of delay to neighboring nodes 206 to the south and east as the clock signal traverses the entire node array 204 of FIG. 2A. Such clock signal propagation continues through the clock distribution network until the clock signal reaches the node 206 (e.g., node 206D) of the node array 204 at an opposite corner from the root node 206.

As the clock signal propagates through the node array 204, nodes 206 in the node array 204 can receive clock signals with substantially the same delay from two other neighboring nodes 206. A recombinant mesh topology can combine the two clock signals received from two neighboring nodes 206 at a given node 206 of the node array 204. For example, in FIG. 2B, the clock signals received via the first input clock wire 222 and the second input clock wire 224 can be combined and received at each of the first inverter 226 and the second inverter 228. In some embodiments, the clock signal is combined by directly connecting the first input clock wire 222 and the second input clock wire 224 together. Other implementations for providing a recombinant mesh topology are also possible.

The clock distribution circuitry disclosed herein allows for flexible array structures, which support a wide range of array designs. For example, a node array 204 can be substantially square with the same number of rows and columns. Alternatively, a node array 204 can be substantially rectangular with a different number of rows than columns. The clock distribution circuitry disclosed herein also provides for a relatively simple restructuring of an array with respect to the clock, which can also allow for relatively late schedule design decisions regarding node array shapes. In contrast, array sizes and shapes with other clock distribution networks are typically expensive decisions to defer due to the amount of clock design time involved. However, in certain cases, such late decisions can result in overall chip design optimization and, thus, can be desirable.

FIG. 2C illustrates another example implementation of the clock distribution circuitry within an example node 206 of the node array 204 of FIG. 2A. With reference to FIG. 2C, the clock distribution circuitry includes a first input clock wire 222, a second input clock wire 224, a second inverter 228, a third inverter 230, a fourth inverter 232, a clock tap point 234, a first output clock wire 236, and a second output clock wire 238. The clock distribution circuitry, in FIG. 2C, for each of the nodes 206 is designed such that output clock wires 236 and 238 of a node 206 are aligned with input clock wires 222 and 224 of neighboring nodes 206. The nodes 206 can be stepped and tiled in the node array 204 such that the output clock wires 236 and 238 align with and electrically connected with the input clock wires 222 and 224 two of the neighboring nodes 206. Using these electrical connections, the node array 204 can be implemented without the use of channels or top-level wiring for the distribution of the clock.

In the example of the clock distribution circuitry, as shown in FIG. 2C, the input wires 222 and 224 can receive an input clock signal from two of the neighboring nodes 206. For example, the first input clock wire 222 receives an input clock signal from the neighboring node 206 above the current node 206, while the second input clock wire 224 receives an input clock signal from the neighboring node 206 to the left of the current node 206. The first and second input clock wires 222 and 224 provide the clock signal to the second inverters 228. The second inverter 228 inverts the clock signal and provides the inverted clock signal to the third and fourth inverters 230 and 232. Each of the third and fourth inverters 230 and 232, invert the inverted clock signal and outputs the resulting clock signal to the first and second output clock wires 236 and 238. The first and second output clock wires 236 and 238 output the clock signal to the neighboring nodes 206 to the right and below the current node 206.

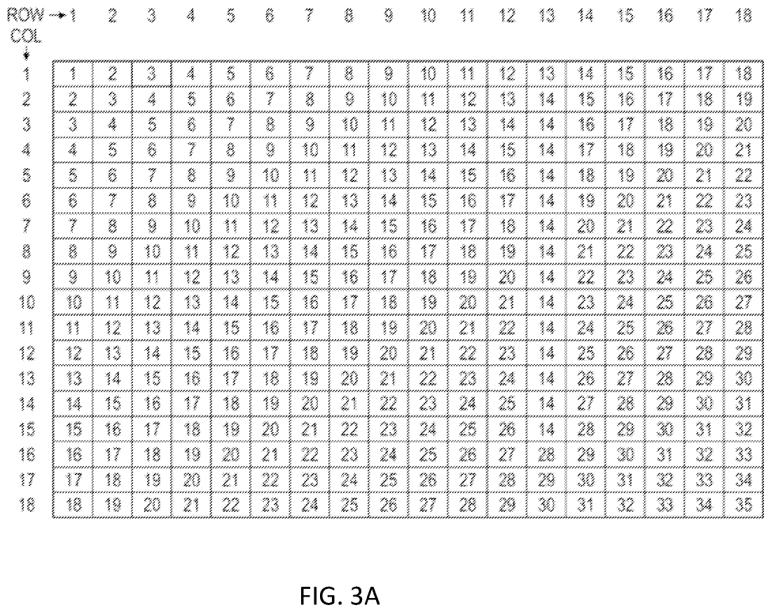

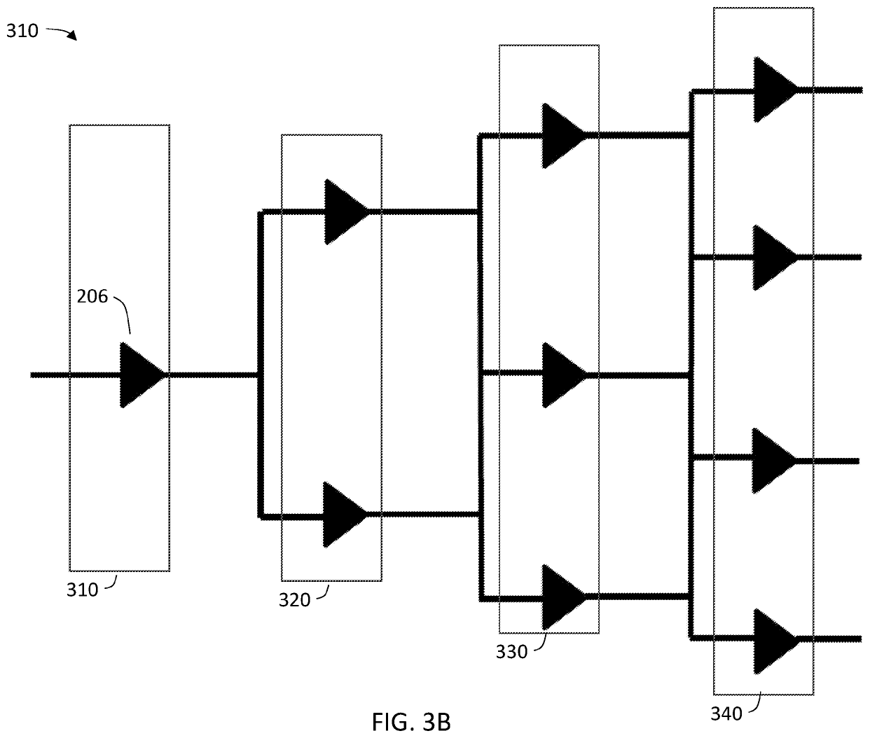

FIG. 3A is a node clock-level map associated with an example node array such as the node array 204 of FIG. 2A. The example node array 204 has 18 rows and 18 columns. With 18 rows and 18 columns, there can be 324 nodes. As another example, a node array 204 can include 360 nodes arranged in rows and columns. Nodes 206 of the node array 204 can have clock distribution circuitry corresponding to that of FIG. 2B, for example. Nodes 206 of the node array 204 can also have clock distribution circuitry corresponding to that of FIG. 2C. This clock map illustrates the number of unit delays for a clock signal output for a node 206 of the node array 204. For example, the root node 206 has 1 unit delay. The two nodes 206 neighboring the root node 206 have 2 unit delays. The nodes 206 on diagonals from southwest to northeast can have the same unit delays. Using the clock distribution circuitry described herein, the unit delays can be fixed offsets. The nodes 206 along these diagonals can receive clock signals having substantially the same timing delay. These diagonals can be referred to as phases or waves. The phases correspond to different clock signal arrival times in the nodes 206. The clock signal distribution corresponds to the map of FIG. 3A can implement a 35 phase mesochronous clock. The number of phases of a mesochronous clock signal for a node array with clock distribution circuitry described herein can be the number of rows plus the number of columns minus one.

In certain embodiments, rather than the clock signal traversing the node array 204 with waves that are formed along a diagonal of the node array 204, the clock distribution network 200 can be configured to generate waves that traverse the node array 204 in the row or column direction. For example, rather than outputting the clock signal to the south and the east, each nodes 206 may output the clock signal to either the south or the east. In this way, the clock signal may propagate in waves that travel to the south or to the east. However, aspects of this disclosure are not limited to a particular direction of travel for the clock signals, and the clock signals can propagate along other diagonals and/or to the north or west.

The offsets of FIG. 3A can be accounted for when routing signals between nodes 206. A signal that is routed from an originating node that generates the signal to a node that is north or west can travel upstream and lose one unit delay in a node array 204 corresponding to FIG. 3A. A signal that is routed from an originating node to a node that is south or east can travel downstream and gain one unit delay in a node array 204 corresponding to FIG. 3A. Signals traveling upstream can be routed faster than signals traveling downstream to account for the unit delay and meet setup and hold time specifications. The timing clock distribution shown in FIG. 3A can also be referred to as a wave clock distribution.

FIG. 3B is a node clock-level topology 310 corresponding to the node clock-level map of FIG. 3A. As shown in FIG. 3B, the node(s) 206 included in groups 310, 320, 330, and 340, can have unit delay of one, two, three, and four, respectively. The nodes 206 included in the same group, can have the same number of unit delays from the clock signal received at the root node.

### Timing Modeling

While timing in a node array can be important for computational accuracy, performance, and so forth, it can be difficult to accurately simulate timing in high replicated node arrays. For example, the size of the network-on-chip (NoC) data buses may explode the netlist size of the node array, and the clock phase variation can cause the inaccuracy for simulating the timing distribution in the node array. Furthermore, available electronic design automation (EDA) software may struggle to compute timings for a node array. In some cases, EDA software may be unable to compute timings for a node array, especially if the node array is large and/or complex. Alternatively, EDA software may take significant time for computing timings for a node array.

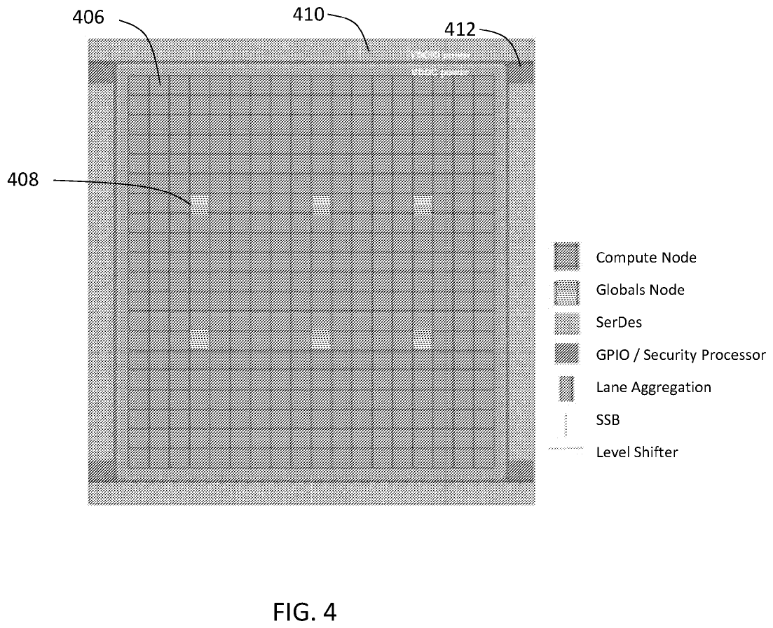

To address at least a portion of the above-described technical challenges, one or more aspects of the present disclosure correspond to systems and methods for modeling the timing of clock signal distribution in a node array. According to the aspects, the timing distribution of the node array can be simulated by modeling the timing delay of the node array based on timing delay analysis on a block of nodes (e.g., a portion of the node array). As described above, each node 206 of the node array 204 can include an instance of the substantially same clock distribution circuitry even if the other circuitry of one or more of the nodes 206 is different than that of other nodes 206. For example, the computing node 406 and globals node 408, shown in FIG. 4, can have the same clock distribution circuitry. Thus, the timing distribution can be modeled by performing timing analysis on one block (e.g., a node). For example, since the signal is travelling in one direction (e.g., upstream or downstream), the time delay according to the signal direction can be determined based on the interface delay between a node and its neighboring (e.g., abutted or adjacent) nodes. This method can be advantageous because it can avoid analyzing time delay for every nodes in the node array and computing the analyzed time delay to model the timing distribution of the node array.

As shown in FIG. 4, in some embodiments, a node array can comprise compute nodes 406, globals nodes 408, SerDes components 410, general purpose input/output (GPIO)/security processing 412, and so forth. Compute nodes 406 can include circuitry for performing processing tasks. Globals nodes 408 may not include circuitry for performing processing tasks. For example, the globals nodes 408 may include PVT sensors to monitor the operating conditions of the node array. In some implementations, compute nodes 406 and globals nodes 408 may both include communication interfaces to enable communication with neighboring nodes. In some implementations, the communication interfaces for compute nodes 406 may be the same as the communication interfaces for globals nodes 408.

In some embodiments, techniques disclosed herein can be used to perform static timing analysis of a heavily replicated array having a plurality of compute nodes 406 and a plurality of globals nodes 408. In some embodiments, a dummy block (which can be similar to or the same as a globals block as described above) can have most internal circuitry removed but can preserve interfaces and/or communication on its edges such that it can interface directly with functional blocks (e.g., compute nodes) in an array. In some embodiments, the array can distribute clock signals to the functional blocks and the dummy blocks using a mesh clock distribution.

In some implementations of a node array, nodes in the node array may only communicate with adjacent nodes. There may not be “flyover” signals, bypass signals, or other signals going across nodes in such implementations. Routes connecting adjacent nodes can be horizontal or vertical. Nodes can be connected to neighboring nodes by horizontal routes and vertical routes. A compute node 406 that is not on the edge of the node array can interface with four neighboring nodes of the node array, two nodes that abut the compute node 406 in the same row of the node array and two nodes that abut the compute node 406 in the same column of the node array. A globals node 408 can interface with four neighboring computer nodes 406 of the node array, two compute nodes 406 that abut the globals node 408 in the same row of the node array and two compute nodes 406 that abut the globals node 408 in the same column of the node array.

As mentioned above, modeling clock distribution for an entire node array can be difficult, time-consuming, or even not possible using available EDA tools. Thus, there is a desire for simplified approaches that can model clock timings accurately.

In some embodiments, a modeling technique can include creating different global static timing model replicas of the functional blocks and dummy blocks. Static timing models for functional blocks can include models for a functional block with different surrounding environments (e.g., fully surrounded by functional blocks, having a dummy block on one side and functional blocks on other sides, etc.). In some embodiments, there can be only a limited number of arrangements of functional and/or dummy blocks around a functional block within a node array. A static timing model for the dummy block can account for the surrounding functional blocks. In some embodiments, a dummy block can be surrounded by functional blocks.

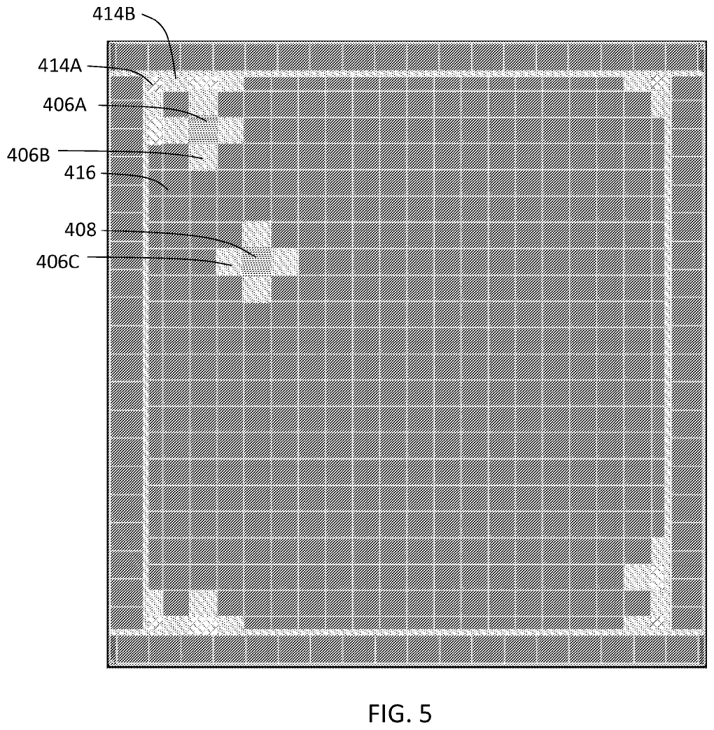

A large node array with mesochronous clocking presents technical challenges for static timing analysis with traditional timing tools. Wide two-dimensional busses can significantly increase the size of a netlist and consequently increase simulation run time, even for hierarchical designs. Timing analysis of the clock signal in node arrays described herein depend on directionality of data propagation with respect to clock propagation direction. Since interfaces are only between neighboring nodes that abut each other in the node array, the timing can be performed with a block group timing model of a node and neighboring nodes with communication interfaces with the node. The block group timing can involve a simulation involving 5 nodes, which can be a small subset of the node array. The block group timing approach can avoid annotation of arrival times and efforts of correlating simulations with an actual design that can be present with other approaches. By creating block groups for each scenario in a node array, the full node array can be accurately simulated based on a few models. The block group timing approach with be discussed with reference to FIG. 5. The timing of the node array in this disclosure can take advantage of one or more of the following simplifications: one block populates most (e.g., 98%) of the array, there are interfaces between abutting neighboring nodes only, the clock phases are systematic and matches, and most clos delay variation is common node.

FIG. 5 shows an example of selecting nodes in a node array for modeling. In some embodiments, timings for the compute node 406A, neighboring nodes 406B around the compute node 406A, the globals node 408, and neighboring nodes 406C around the globals node 408 can be modeled, while the other nodes 416 can be depopulated. In addition, in some embodiments, a lane aggregator 414A and neighboring circuitry 414B of the node array can be modeled by modeling the corners, while other nodes 416 in the node array can be depopulated by removing internal circuitry from a timing model. Such an approach can reduce the number of nets, logic gates, wires, parasitic capacitances, etc., to be modeled significantly. For example, the number of logic gates to be modeled can be reduced by about 80%, about 90%, etc. The reduction can depend on, for example, the number of nodes in the node array, the types of nodes in the node array, and so forth. Such an approach can provide significant speed improvements in modeling and can be especially beneficial for replicated designs without global signals. Modeling computation times can be reduced from, for example, days or even weeks to hours.

Referring to FIG. 5, the compute node 406A, the neighboring nodes 406B around the compute node 406A, the globals node 408, the neighboring nodes 406C around the globals node, the lane aggregator 414A, and neighboring circuitry 414B can be utilized to model the timing of clock distribution in the node array. The clock timing in the node array can be simulated using timing models for a small subset of the node array. A compute node 406A and neighboring compute nodes 406B can be simulated to create a timing model for a compute node. The timing model for the compute node can be used for each compute node of the array. The globals node 408 and neighboring compute nodes 406C can be simulated to create a timing model for a globals node. The timing model for the globals node can be used for each globals node of the array.

In some embodiments, the time delay of the clock signal between the compute node 406A and each neighboring node 406B can be created based on the determined delay. Each other compute node of the node array can use the same timing mode as the compute node 406A. For example, since each node of the node array includes an instance of the same clock distribution circuitry and interface circuitry and abuts instances of the same neighboring nodes, the same timing model can be used for each of the compute nodes in FIG. 3A.

The time delay of the clock signal between the globals node 408 and each of the neighboring compute nodes 406C can be created based on the determined delay. Each other globals node of the node array can use the same timing mode as the globals node 408.

The time delay of the clock signal between lane aggregator 414A and neighboring circuitry 414B can be determined and used for each similar instance of such circuitry. A model can be determined and used for each similarly situated lane aggregator. The lane aggregator models can simulate device-under-test (DUT) block and associated interface paths.

Models of the node array can cover functional blocks (e.g., compute nodes) and depopulated blocks. Models of the node array can cover global communication node timing with a fraction of the size of the design without any gray box models.

A method of generating a model of a circuit design with replicated instances of a circuit block (e.g., a node array) can include parsing through a hardware description language (e.g., Verilog) model of the circuit design and generating a model of the circuit block (e.g., a functional block). The method can also include removing redundant similar instances of the circuit block to reduce the size of the model. The same or a similar method can be performed for all other types of block instances of a design (e.g., a globals block). Then the model can include only unique scenarios. Static timing analysis can be performed on the model.

### Worst Case Timing

In some implementations of a node array, a block-group timing model based on a block of nodes of the node array is modeled to include various timing delay scenarios. For example, the delay between any two node clock arrival points in the node array can be different. The block distribution can be variable. For example, the delay between two nodes in the node array (e.g., near the middle of a node array) can be from the delay between two nodes near the edge of the node array. This can happen because, for example, capacitance can be different in different regions of the node array (e.g., higher in the middle) due to manufacturing processes.

In some embodiments, timings can be simulated to determine the worst cases for early arrival and late arrival. This information can be used to ensure that any node in the array can meet arrival time specifications and hold time specifications. Such an approach can be employed to, for example, ensure that even if modeling is done using a particular node or set of nodes in the array, the modeling results can be applied to any node in the node array.

In some embodiments, a mesh clock distribution can travel in a wave-like distribution across a node array. EDA tools can allow clock delay to be annotated for early and late arrivals of the clock signal. In some embodiments, static timing analysis can be run using only a worst case scenario. Clock arrival differences can be generated between different compute nodes and global nodes, and a worst case scenario for any node for arrivals across the node array can be identified. Static timing analysis can be run on the worst possible combination of arrivals for all nodes of a node array (e.g., all compute nodes and globals nodes). By applying the worst case scenario, the runtime of static timing analysis for the node array can be reduced. The worst case scenarios for both setup time and hold time can be applied. At the same time, this can ensure that static timing for the design converges for all combinations of communication traffic going between any two adjacent nodes of the node array.

In contrast, in a typical approach, static timing analysis may be performed for all nodes in an array, which can involve significant computational resources to complete.

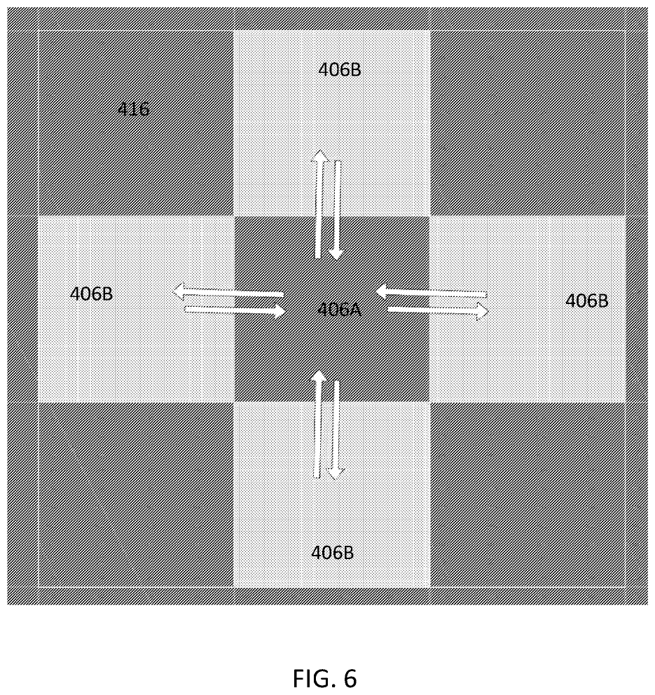

Timing can be generated between any two nodes of a node array. FIG. 6 illustrates determining part of a node array (e.g., block-group of node array) timing to and from a node (e.g., compute node 406A) and adjacent nodes (e.g., neighboring compute nodes 406B) in both the vertical and horizontal directions. The worst early and late arrivals can be annotated for these adjacent nodes. This can ensure that setup time and hold time specifications are met.

Worst case timing data can be generated by parsing through node array circuit simulation (e.g., SPICE simulation) results across the entire grid. The fastest and slowest arrival times through the buffers can be selected. The delay of the buffers can be annotated in the timing model. This timing model can be optimized.

The worst case timing data can be used with the model of the node array described in the previous section. Since only unique scenarios are used in the model, the worst case for setup time and the worst case for hold time can be used with each unique scenario in the model. Together the model and the worst case timing data can be used to efficiently simulate static timing for the node array and ensure that setup and hold time specifications are met.

The worst case timing data can be used to modify the design of clock distribution circuitry. If the worst case timing is outside of a timing specification, the clock distribution circuitry can be adjusted until the timing specification is met. Adjusting the clock distribution circuitry can involve adjusting the size of one or more clock drivers (e.g., increasing or decreasing inventor size depending on whether setup time or hold time specifications are not met) and/or adjusting the width of one or more wires that carry the clock signal (e.g., widening or narrowing wires whether setup time or hold time specifications are not met). Such adjustment of clock distribution circuitry can be applied to each node of the array. Design automation tools can automate the process of adjusting clock distribution circuitry until a worst case timing meets timing specifications. In some other applications, a circuit designer can use worst case timing data to update clock distribution circuitry.

### Example Embodiment of Node Array Timing Distribution Model

In some embodiments, the node array timing distribution model can be used to simulate the clock timing in a node array. For example, the simulation results of the node array timing distribution model may used to determining a worst case scenario of clock timing in the node array. These simulation results can be utilized for designing a clock distribution network include, the interface and/or inverters and/or wires that carry signals between nodes of the node array.

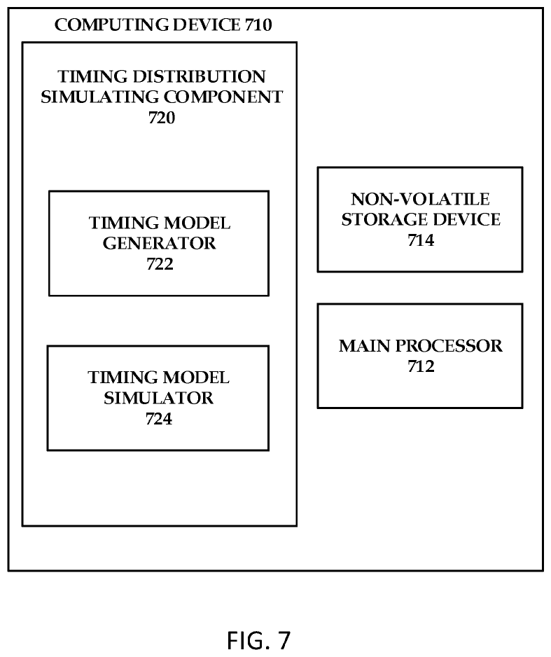

FIG. 7 illustrates an example of a computing device 710 that can simulate clock timing distribution across a node array. As shown in FIG. 7, the computing device 710 implements the timing distribution simulating component 720, a non-volatile storage device 714, and a main processor 712.

In some examples, the main processor 712 may provide dedicated computing resources to be used by the timing distribution simulating component 720. Furthermore, the main processor 712 may utilize the designated computing resource to process data generated from the timing distribution simulating component 720, according to examples as disclosed herein.

As shown in FIG. 7, the timing distribution simulating component 720 can include a timing model generator 722 and timing model simulator 724. The timing model generator 722 can be configured to model time delay of the node array by analyzing timing delay on a block of nodes ((e.g., a portion of the node array). With reference to FIGS. 4 and 5, the timing model generator 722 may utilize a modeling technique that includes creating different global static timing model replicas of the functional blocks and dummy blocks. Static timing models for functional blocks can include models for a functional block with different surrounding environments (e.g., fully surrounded by functional blocks, having a dummy block on one side and functional blocks on other sides, etc.). In some embodiments, there can be only a limited number of arrangements of functional and/or dummy blocks around a functional block within a node array. A static timing model for the dummy block can account for the surrounding functional blocks. In some embodiments, a dummy block can be surrounded by functional blocks. Timing analysis of the clock signal in node arrays described herein depend on directionality of data propagation with respect to clock propagation direction. Since interfaces are only between neighboring nodes that abut each other in the node array, the timing can be performed with a block group timing model of a node and neighboring nodes with communication interfaces with the node. The block group timing can involve a simulation involving 5 nodes (e.g., a middle node with abutted neighboring nodes), which can be a small subset of the node array. The block group timing approach can avoid annotation of arrival times and efforts of correlating simulations with an actual design that can be present with other approaches. By creating block groups for each scenario in a node array, the full node array can be accurately simulated based on a few models.

In some embodiments, the timing model generator 722 may model select a compute node, neighboring nodes (e.g., 4 abutted neighboring nodes) around the compute node, the globals node, and neighboring nodes around the globals node, while the other nodes in the node array can be depopulated. In addition, in some embodiments, a lane aggregator and neighboring circuitry of the node array can be modeled by modeling the corners, while other nodes in the node array can be depopulated by removing internal circuitry from a timing model. Such an approach can reduce the number of nets, logic gates, wires, parasitic capacitances, etc., to be modeled significantly. For example, the number of logic gates to be modeled can be reduced by about 80%, about 90%, etc. The reduction can depend on, for example, the number of nodes in the node array, the types of nodes in the node array, and so forth. Such an approach can provide significant speed improvements in modeling and can be especially beneficial for replicated designs without global signals. Modeling computation times can be reduced from, for example, days or even weeks to hours. In some embodiments, the models generated from the timing model generator 722 can be stored in the non-volatile storage device 714.

The timing model simulator 724 can be configured to simulate the models stored in the non-volatile storage device 714. In some embodiments, the timing model simulator 724 may access to the models by accessing to the non-volatile storage device 714. In some embodiments, the model that includes a compute node and neighboring compute nodes can be simulated to create a timing model for the compute node. The timing model for the compute node can also be used for each compute node of the array. The globals node and neighboring compute nodes can also be simulated to create a timing model for a globals node. The timing model for the globals node can be used for each globals node of the array.

In some embodiments, the timing model simulator 724 creates the time delay of the clock signal between the compute node and each neighboring node based on the determined delay. Each other compute node of the node array can use the same timing mode as the compute node. For example, since each node of the node array includes an instance of the same clock distribution circuitry and interface circuitry and abuts instances of the same neighboring nodes, the same timing model can be used for each of the compute nodes in FIG. 3A. The time delay of the clock signal between the globals node and each of the neighboring compute nodes can also be created based on the determined delay. Each other globals node of the node array can use the same timing mode as the globals node.

In some embodiments, the timing model simulator 724 may simulate the node array by modeling the node array that covers functional blocks (e.g., compute nodes) and depopulated blocks. A method of generating a simulating model of a circuit design with replicated instances of a circuit block (e.g., a node array) can include parsing through a hardware description language (e.g., Verilog) model of the circuit design and generating a model of the circuit block (e.g., a functional block). The method can also include removing redundant similar instances of the circuit block to reduce the size of the model. The same or a similar method can be performed for all other types of block instances of a design (e.g., a globals block). Then the model can include only unique scenarios.

In some embodiments, the timing model simulator 724 performs timing analysis to determine the worst case timing data and include the determined worst case timing data in the simulation. For example, timing can be generated between any two nodes of a node array (e.g., FIG. 6 illustrates determining part of a node array (e.g., block-group of node array) timing to and from a node (e.g., compute node 406A) and adjacent nodes (e.g., neighboring compute nodes 406B) in both the vertical and horizontal directions). The worst early and late arrivals can be annotated for these adjacent nodes. This can ensure that setup time and hold time specifications are met.

Worst case timing data can be generated by parsing through node array circuit simulation (e.g., SPICE simulation) results across the entire grid. The fastest and slowest arrival times through the buffers can be selected. The delay of the buffers can be annotated in the timing model. This timing model can be optimized.

The worst case timing data can be used with the model of the node array generated by the timing model generator 722. Since only unique scenarios are used in the model, the worst case for setup time and the worst case for hold time can be used with each unique scenario in the model. Together the model and the worst case timing data can be used to efficiently simulate static timing for the node array and ensure that setup and hold time specifications are met.

In some embodiments, the worst case timing data can be used to modify the design of clock distribution circuitry. If the worst case timing is outside of a timing specification, the clock distribution circuitry can be adjusted until the timing specification is met. Adjusting the clock distribution circuitry can involve adjusting the size of one or more clock drivers (e.g., increasing or decreasing inventor size depending on whether setup time or hold time specifications are not met) and/or adjusting the width of one or more wires that carry the clock signal (e.g., widening or narrowing wires whether setup time or hold time specifications are not met). Such adjustment of clock distribution circuitry can be applied to each node of the array. Design automation tools can automate the process of adjusting clock distribution circuitry until a worst case timing meets timing specifications. In some other applications, a circuit designer can use worst case timing data to update clock distribution circuitry.

To simplify the discussion and not to limit the present disclosure, FIG. 7 illustrates only the timing distribution simulating component 720, non-volatile storage device, and main processor, though multiple sub-components or systems may be used.

### Applications, Terminology, and Conclusion

Node arrays disclosed herein can be implemented in a variety of processing systems. Such processing systems can used in and/or specifically configured for high performance computing and/or computationally intensive applications, such as neural network training, neural network inference, machine learning, artificial intelligence, complex simulations, or the like. In some applications, the processing system can be used to perform neural network training. For example, such neural network training can generate data for an autopilot system for vehicle (e.g., an automobile), other autonomous vehicle functionality, or Advanced Driving Assistance System (ADAS) functionality.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

1. A method of simulating a node array, the method comprising:
accessing a timing model of a compute node of the node array that is stored in non-transitory computer readable memory, wherein the timing model of the compute node represents timing data associated with clock signal propagation between the compute node and four neighboring nodes of the node array that each abut the compute node; and
simulating, using one or more computers, clock signal timing for a majority of the nodes of the node array using the timing model of the compute node.

2. The method of claim 1, further comprising determining a worst case timing for the clock signal in the node array based on the simulating.

3. The method of claim 2, further comprising adjusting a clock distribution network of the node array based on the worst case timing.

4. The method of claim 3, wherein adjusting the clock distribution network comprises updating of one or more files that represent circuitry of the node array.

5. The method of claim 2, further comprising accessing a timing model of a globals node of the node array that is stored in the non-transitory computer readable memory, wherein the determination is based on a simulation of clock signal timing that uses the timing model of the globals node.

6. The method of claim 1, wherein the simulating comprises simulating mesochronous clocking in the node array.

7. The method of claim 1, wherein the timing model of the node array models the compute node receiving the clock signal from a first pair of the four neighboring nodes and the compute node providing the clock signal to a second pair of the four neighboring nodes, wherein the clock signal is delayed by one unit of delay in the compute node relative to in the first pair of neighboring nodes, and wherein the clock signal is delayed by two units of delay in the second pair of neighboring nodes relative to in the first pair of neighboring nodes.

8. The method of claim 1, wherein the timing model of the node array is a block group timing model.

9. The method of claim 1, wherein the majority of the nodes of the node array comprise at least 90% of the nodes of the node array.

10. The method of claim 8, wherein the node array consists essentially of instances of the compute node and instances of a globals node.

11. The method of claim 1, further comprising generating the timing model of the compute node by at least simulating clock signal propagation between the compute node and the four neighboring nodes.

12. (canceled)

13. (canceled)

14. A system for simulating clock timing distribution across a node array that includes a plurality of compute nodes, the system comprising:
one or more computing devices configured to store a timing model, corresponding to a compute node and four neighboring compute nodes that each neighboring compute code is abutted to the compute node, wherein individual computing devices of the one or more computing devices are configured to:
access the timing model of the compute node; and
simulate, using a computing device, clock signal timing distribution for a majority of the nodes of the node array using the timing model of the compute node.

15. A non-transitory computer-readable storage medium storing instructions to simulate clock timing distribution across a node array, the instructions, when executed by a processor, cause the processor to perform operations comprising:
accessing a timing model of a compute node, wherein the timing model of the compute node represents timing data associated with clock signal propagation between the compute node and four neighboring nodes of the node array that each abut the compute node; and
simulating, using a computing device, clock signal timing distribution for a majority of the nodes of the node array using the timing model of the compute node.

16. The non-transitory computer-readable storage medium of claim 15, wherein the operations further comprise determining a worst case timing for the clock signal in the node array based on the simulating.

17. The non-transitory computer-readable storage medium of claim 16, wherein the operations further comprise_adjusting a clock distribution network of the node array based on the worst case timing.

18. (canceled)

19. The non-transitory computer-readable storage medium of claim 16, wherein the operations further comprise accessing a timing model of a globals node of the node array that is stored in the non-transitory computer readable medium, wherein the determination is based on a simulation of clock signal timing that uses the timing model of the globals node.

20. The non-transitory computer-readable storage medium of claim 15, wherein the simulating comprises simulating mesochronous clocking in the node array.

21. The non-transitory computer-readable storage medium of claim 15, wherein the timing model of the node array models the compute node receiving the clock signal from a first pair of the four neighboring nodes and the compute node providing the clock signal to a second pair of the four neighboring nodes, wherein the clock signal is delayed by one unit of delay in the compute node relative to in the first pair of neighboring nodes, and wherein the clock signal is delayed by two units of delay in the second pair of neighboring nodes relative to in the first pair of neighboring nodes.

22. The non-transitory computer-readable storage medium of claim 15, wherein the timing model of the node array is a block group timing model.

23. The non-transitory computer-readable storage medium of claim 15, wherein the majority of the nodes of the node array comprise at least 90% of the nodes of the node array.

24. (canceled)

25. (canceled)
